(19) United States
(12) Patent Application Publication
(10) Pub. No.: US 2009/0108447 A1
(43) Pub. Date: Apr. 30, 2009

(54) SEMICONDUCTOR DEVICE HAVING A FINE PITCH BONDPAD

(75) Inventors: Sang-Gui JO, Seoul (KR); Seung-Kon MOK, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 12/243,621

(22) Filed: Oct. 1, 2008

(30) Foreign Application Priority Data
Oct. 25, 2007 (KR) 2007-0107816

(51) Int. Cl. H01L 23/49

(52) U.S. Cl. 257/738; 257/E23.024

(57) ABSTRACT

A semiconductor device is provided, including a semiconductor chip having fine pitch bond pads, dummy bond pads, and ball bonds formed on the semiconductor chip, and electrically connected to circuits of the semiconductor chip, where the width of each fine pitch bond pad is less than the diameter of each ball bond. The dummy bond pads are formed between adjacent bond pads and have a plurality of lands not connected to each other. The ball bonds may be connected to the bond pads in a zigzag configuration and are partially connected to the dummy bond pads. Accordingly, the pitch between bond pads is reduced while preventing short circuits between adjacent ball bonds.

### CROSS-REFERENCE TO RELATED PATENT APPLICATION

This application claims the benefit of Korean Patent Application No. 10-2007-0107816, filed on Oct. 25, 2007, in the Korean Intellectual Property Office, the disclosure of which is hereby incorporated by reference.

### BACKGROUND (OF THE INVENTIVE CONCEPT)

The present inventive concept relates to a semiconductor device, and more particularly, to a semiconductor device, such as a semiconductor chip, a semiconductor package, or a semiconductor module, having fine pitch bond pads and also having a sufficient adhesive strength between bond pads and ball bonds.

In the past, semiconductor packaging technology was developed by focusing on how to route signal lines in a semiconductor chip to the outside how to effectively transfer heat generated in the semiconductor chip to the outside, and how to effectively protect the semiconductor chip from external impact.

Early semiconductor packages were developed as insertion semiconductor packages, such as dual in-line packages (DIPs), and surface mounting semiconductor packages, such as thin quad flat packages (TQFPs) and thin small out-line packages (TSOPs), these packages including pin grid arrays (PGAs) with fine pitches.

Currently, semiconductor packages are developed with a focus on high integration in light, thin, and small semiconductor packages to cope with the miniaturization of electronic products. Accordingly, semiconductor packages are being developed into ball grid arrays (BGAs) using solder balls or bumps as external connection terminals, chip scale packages (CSPs), and wafer level packages (WLPs). However, continued development of semiconductor packages is advancing to develop packages with complicated structures, such as, multi-chip packages (MCPs), multi-chip modules (MCMs), and system in packages (SIPs).

There are two classifications of interconnection techniques used in MCPs, MCMs, and SIPs: flip-chip, and non-flip-chip packaging techniques. The flip-chip packaging technique achieves interconnection by using bumps, but the non-flip chip packaging technique does not. Most non-flip chip packaging techniques us wire bonding as the interconnection technique within a semiconductor package.

In semiconductor packages such as BGAs, MCPs, and SIPs, the number of input/output (I/O) terminals in a semiconductor chip increases in accordance with the trend toward miniaturization and high integration. As such, the realization of a fine pitch for bond pads in semiconductor chips used in non-flip chip packages becomes an essential technique for the development of these advanced semiconductor packages. FIG. 1 is a plan view of bond pads 10 of a conventional semiconductor device. Referring to FIG. 1, the bond pads 10 of the conventional semiconductor device, each of which is a single plate, are connected to corresponding circuit lines 20 within a semiconductor chip, and the bond pads 10 are insulated from each other by a final protection film. However, when wire bonding is performed using gold wires 40, an electrical short circuit may occur when a ball bond 30 formed on a bond pad 10 slightly touches an adjacent ball bond 30. As a result, realization of a fine pitch A between bond pads 10 may be limited.

### SUMMARY

Embodiments of the present inventive concept provide a semiconductor device having fine pitch bond pads in which an interval between bond pads may be reduced while preventing a reduction of the area where wire bonding is performed. These embodiments help reduce adhesion between ball bonds.

An embodiment of the present inventive concept includes a semiconductor device comprising bond pads, a semiconductor chip, fine pitch bond pads, and dummy pads. The fine pitch bond pads are formed on the semiconductor chip and are electrically connected to circuits in the semiconductor chip, where the width of each fine pitch bond pad is less than the diameter of each ball bond. The dummy bond pads are formed between adjacent bond pads on the semiconductor chip, and are not electrically connected to the semiconductor chip circuits.

### BRIEF DESCRIPTION OF THE DRAWINGS

The above and other features and advantages of the present inventive concept will become more apparent by describing in detail exemplary embodiments thereof with reference to the attached drawings in which:

FIG. 1 is a plan view of bond pads of a conventional semiconductor device;

FIG. 2 is a plan view of bond pads of a semiconductor device according to an embodiment of the present inventive concept;

FIG. 3 is a plan view of bond pads of a semiconductor device according to another embodiment of the present inventive concept;

FIG. 4 is a plan view of a wire bonding structure of a semiconductor device according to another embodiment of the present inventive concept; and

FIGS. 5 and 6 are plan views illustrating a structure of a semiconductor chip according to another embodiment of the present inventive concept.

### DETAILED DESCRIPTION OF THE EMBODIMENTS

The present embodiments of the inventive concept will now be described more fully with reference to the accompanying drawings, in which exemplary embodiments of the inventive concept are shown.

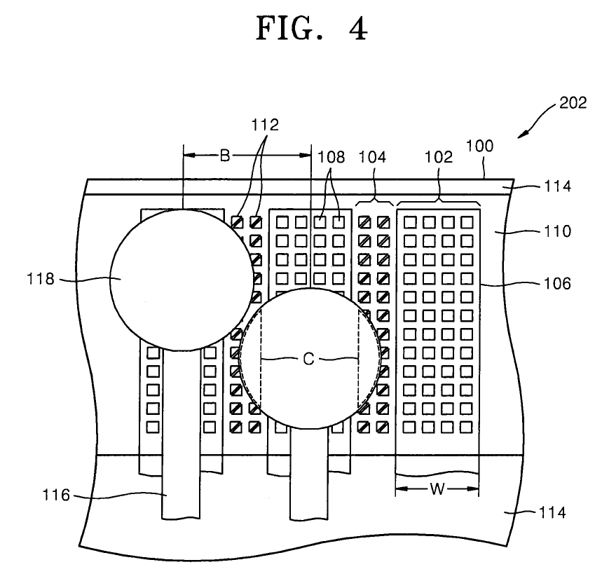

FIG. 2 is a plan view of fine pitch bond pads 102 of a semiconductor device 200 according to an embodiment of the present inventive concept. Referring to FIG. 2, the semiconductor device 200 comprises fine pitch bond pads 102formed on a semiconductor chip 100. The semiconductor chip 100 may be any type as long as bond pads can be formed thereon. The fine pitch bond pads 102 on the semiconductor device 200 are electrically connected to circuits 106 formed in the semiconductor chip 100, The width W of each fine pitch bond pad 102 is less than the diameter of each ball bond 118 (see FIG. 4). Gold wires 116 (also in FIG. 4), are connected to the bond pads 102 via bumps 118. Each of the bond pads 102 is connected to a corresponding circuit line 106, and includes a plurality of small lands 108 which are separated from each other.

The semiconductor device 200 according to the current embodiment also includes dummy bond pads 104 which are each formed between adjacent bond pads 102 and are not connected to the circuit lines 106. Similar to bond pads 102, each of the dummy bond pads 104 includes a plurality of small lands 112 that are separated from each other.

The semiconductor device 200 according to the current embodiment may include a passivation layer 114, which is used as a final film for protecting a semiconductor chip, and is formed in a circuit region instead of the region 110 that includes the bond pads 102 and the dummy bond pads 104.

Alternatively, the semiconductor device 200 may have passivation layer 114 formed between the bond pads 102 as in a conventional bond pad configuration. The small lands 112 of each of the dummy bond pads 104 may be formed at regular intervals between the bond pads 102. The lands 108 of the bond pads 102 and the lands 112 of the dummy bond pads 104 may be designed to have different shapes or colors so that the bond pads 102 and the dummy bond pads 104 can be easily distinguished from each other. The functions of the dummy bond pads 104 will be described later with reference to FIG. 4.

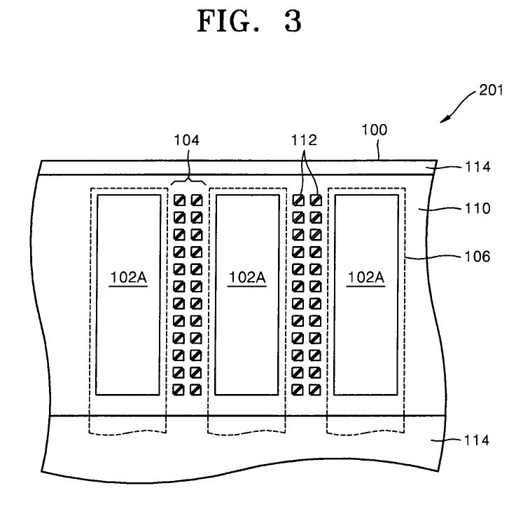

FIG. 3 is a plan view of a semiconductor device 201 that includes fine pitch bond pads according to another embodiment of the present inventive concept. Referring to FIG. 3, although the bond pads 102 may be each comprised of a plurality of small lands as illustrated in FIG. 2, the bond pads 102 may be designed into plate bond pads 102A which are connected to the circuits 106, as shown in FIG. 3. In other words, the semiconductor device 201 may include a semiconductor chip 100, plate bond pads 102A where the width of each plate bond pad 102A is less that the caliber of each ball bond 102, and dummy bond pads 104 which are formed between the bond pads 102A. Additionally, the dummy bond pads 104 are not electrically connected to the circuits 106, and each includes a plurality of small lands 112 which are separated from each other.

As in the embodiment of FIG. 2, the bond pads 102A and the dummy bond pads 104 may be designed to have different colors so that they can be easily and visually identified from each other. Additionally, the passivation layer 114 may not be formed on the region 110 where the bond pads 102A and dummy bond pads 104 are arranged.

FIG. 4 is a plan view of a wire bonding structure of a semiconductor device 202 according to another embodiment of the present inventive concept.

Referring to FIG. 4, the semiconductor device 202 according to the current embodiment may include a semiconductor chip 100, fine pitch bond pads 102, dummy bond pads 104, and ball bonds 118. The fine pitch bond pads 102 are formed on the semiconductor chip 100 and are electrically connected to the circuits 106 of the semiconductor chip, where the width W of each fine pitch bond pad 102 is less than the diameter of each ball bond 118. The dummy bond pads 104 are each comprised of a plurality of lands 112 which are arranged between the bond pads 102 at regular intervals and are separated from each other. The ball bonds 118 are connected to the bond pads 102 in a zigzag configuration, but do not generate electrical short-circuits therebetween although portions C of the ball bonds 118 are connected to the dummy bond pads 104.

The semiconductor device 202 according to the current embodiment may be an advanced semiconductor package, such as a ball grid array (BGA), a multi-chip package (MCP), a system in package (SIP), or a memory module such as a multi-chip module (MCM). In FIG. 4, each of the bond pads 102 is comprised of a plurality of lands 108 which are not connected to each other. However, the bond pads 102 may be replaced by the plate bond pads 102A of FIG. 3.

The semiconductor device 202 according to the current embodiment includes spaces between the bond pads 102 where the dummy bond pads 104 may be arranged. Accordingly, the fine pitch bond pads 102 may be formed by setting the width W of each bond pad 102 to be less than the caliber of each ball bond 118. Therefore, two adjacent ball bonds 118 share a space between bond pads 102 at a predetermined ratio and accordingly use the space as a wire bonding space. However, since the dummy bond pads 104 are connected to the adjacent ball bonds 118 and are each comprised of a plurality of small lands 112 that are separated from each other, the dummy bond pads 104 do not cause an electrical short circuit therebetween.

In general, when the width W of each bond pad 102 is less than the width of each ball bond 118, defective semiconductor devices are detected in, for example, a bond pull test (BPT) or a bond shear test (BST). The BPT is a reliability test where the adhesive strength between the bond pads 102 and the ball bonds 118 is checked by pulling the wires 116 up with a predetermined force. The BST is a reliability test where the adhesive strength between the bond pads 102 and the ball bonds 118 is checked by pulling the ball bonds 118 sideways. It is therefore more difficult to design the bond pads 102 than the ball bonds 118 because when the bond pads 102 do not sufficiently adhere to the ball bonds 118, a large number of defective semiconductor devices may be detected in a reliability test.

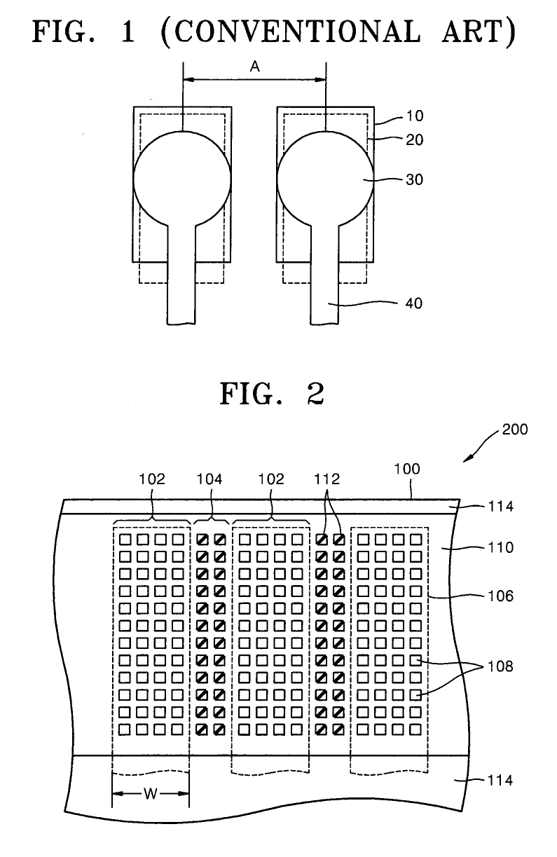

However, the current embodiment of FIG. 4 uses dummy bond pads 104 comprised of small lands 112, which are separated from each other. In other words, the dummy bond pads 104 contribute to the design of bond pads 102 separated from each other at fine pitches, and the portions C of the ball bonds 118 reinforce the adhesion of the ball bonds 118 to the bond pads 102. As a result, the current embodiment of FIG. 4 provides higher adhesion of the ball bonds 118 to the bond pads 102 than when the bond pads 102 are insulated from each other by an insulation film such as a passivation layer, as in FIG. 1, because the ball bonds 118 have higher adhesive strengths when bonding with metal than when bonding with the insulation film.

When the dummy bond pads 104 are arranged between adjacent bond pads 102, it is therefore expected that a pitch B between bond pads 102 can be designed about 23% smaller than the pitch A between conventional bond pads 10 of FIG. 1. Although the number of input/output (I/O) terminals in advanced semiconductor packages, such as MCPs, SIPs, and BGAs, increases, the pitch between bond pads can thus be decreased. Consequently, highly-integrated, small-sized semiconductor devices can be obtained.

The lands 108 of the bond pads 102 and the lands 112 of the dummy bond pads 104 may be designed to have different shapes and colors so that occurrence or non-occurrence of electrical short-circuits can be easily and visually determined. Although the rectangular lands 108 and 112 are illustrated in FIGS. 2 through 4, various changes in the shapes of the lands 108 and 112 may be made.

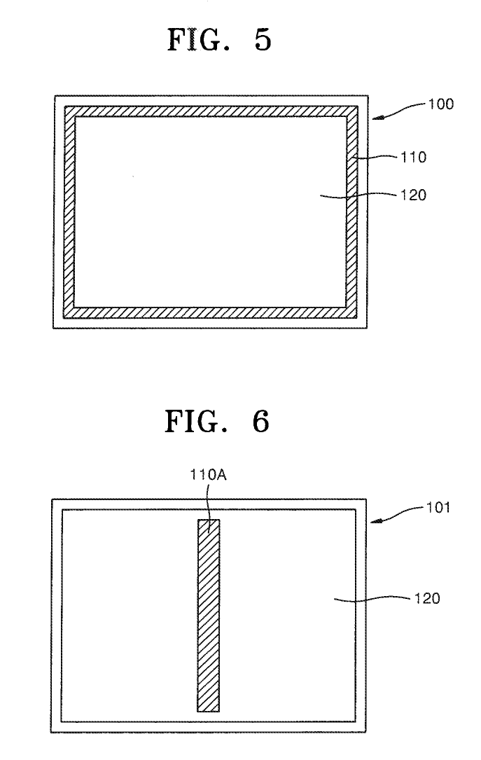

FIGS. 5 and 6 are plan views for illustrating a structure of a semiconductor chip 100 according to another embodiment of the present inventive concept.

Referring to FIGS. 5 and 6, the semiconductor device bond pads according to the current embodiment include fine pitch bond pads, but do not include a passivation layer located on a bonding region 110. Instead, the semiconductor device according to the current embodiment includes a semiconductor chip 100, a passivation region formed on a circuit region 120 of the semiconductor chip 100, and a wire bonding region 110. The passivation layer is a final film for protecting a semiconductor chip. The wire bonding region 110, which is comprised of bond pads and dummy bond pads, may be shaped like a belt on the semiconductor chip 100, and has no passivation layers formed thereon.

As in FIGS. 2 and 3, the wire bonding region 110 includes bond pads which are electrically connected to circuits of the semiconductor chip 100. The width of each bond pad is less than the diameter of each ball bond. The dummy bond pads each include a plurality of lands which are arranged at regular intervals between the bond pads and are not connected to each other. The belt wire bonding region 110 may form a rectangle 110 as in FIG. 5 or a straight line 110A as in FIG. 6.

According to an embodiment of the inventive concept, a plurality of small dummy bond pads are formed between bond pads, and portions of ball bonds are located over the small dummy bond pads during wire bonding. The fine pitch bond pads are capable of preventing electrical short-circuits between adjacent ball bonds. Consequently, although the number of I/O terminals in advanced semiconductor packages may increase, bond pads having fine pitches can be efficiently formed.

In addition, the small dummy bond pads arranged between bond pads increase adhesive strength of bond pads that have widths less than the diameters of the ball bonds. Thus, although the pitch between bond pads decreases, reliable bondability is maintained.

Moreover, the dummy bond pads and the bond pads are designed to have different shapes and colors. Thus, electrical short-circuits between adjacent ball bonds can be easily monitored.

While the present inventive concept has been particularly shown and described with reference to exemplary embodiments thereof, it will be understood by those of ordinary skill in the art that various changes in form and details may be made therein without departing from the spirit and scope of the present inventive concept as defined by the following claims.

What is claimed is:

1. A semiconductor device comprising:
a semiconductor chip;
fine pitch bond pads formed on the semiconductor chip and electrically connected to circuits of the semiconductor chip; and
dummy bond pads formed between adjacent bond pads on the semiconductor chip, where the dummy bond pads are not electrically connected to the circuits of the semiconductor chip.

2. The semiconductor device of claim 1, wherein each of the bond pads is a single plate.

3. The semiconductor device of claim 1, wherein the bond pads and the dummy bond pads are constructed and arranged to connect to corresponding ball bonds and when so connected, the dummy bond pads are partially connected to the ball bonds without generating electrical short circuits in the semiconductor chip circuits.

4. The semiconductor device of claim 3, wherein each of the bond pads is comprised of a plurality of small lands that are electrically connected to the circuits of the semiconductor chip and are separated from each other.

5. The semiconductor device of claim 3, wherein each of the dummy bond pads is comprised of a plurality of small lands that are not electrically connected to the circuits of the semiconductor chip and are separated from each other so as not to generate electrical short-circuits.

6. The semiconductor device of claim 5, wherein spaces between adjacent bond pads are at least partially filled with the lands of the dummy bond pads at regular intervals.

7. The semiconductor device of claim 6, wherein the lands of the dummy bond pads have different shapes from the bond pads.

8. The semiconductor device of claim 6, wherein the lands of the dummy bond pads have different colors from the bond pads.

9. A semiconductor device comprising:
a semiconductor chip;
fine pitch bond pads formed on the semiconductor chip and electrically connected to circuits in the semiconductor chip;
dummy bond pads formed between adjacent bond pads, the dummy bond pads including a plurality of lands not connected to each other; and
ball bonds connected to the bond pads in a zigzag configuration, and partially connected to the dummy bond pads, the bond balls being configured to prevent a short circuit between adjacent ball bonds, and the widths of the fine pitch bond pads being less than diameters of corresponding ball bonds.

10. The semiconductor device of claim 9, wherein the semiconductor device is a semiconductor package.

11. The semiconductor device of claim 9, wherein the semiconductor device is a semiconductor module.

12. The semiconductor device of claim 9, wherein each of the bond pads is a single plate.

13. The semiconductor device of claim 9, wherein each of the bond pads is comprised of a plurality of lands apart from each other.

14. The semiconductor device of claim 13, wherein the lands of the bond pads have different colors from the dummy bond pads.

15. The semiconductor device of claim 13, wherein the lands of the bond pads have different shapes from the lands of the dummy bond pads.

16. A semiconductor device comprising:
a semiconductor chip;
a passivation region formed on the semiconductor chip; and
a wire bonding region formed on the semiconductor chip, the wire bonding region shaped like a belt and exposed where no passivation layers are formed, wherein the wire bonding region comprises:
fine pitch bond pads formed on the semiconductor chip and electrically connected to circuits of the semiconductor chip, wherein the widths of the fine pitch bond pads are respectively less than diameters of a corresponding ball bond pads, and
dummy bond pads each comprising a plurality of lands arranged between adjacent bond pads at regular intervals and not connected to each other.

17. The semiconductor device of claim 16, wherein the wire bonding region is a rectangular belt formed along edge portions of the semiconductor chip.

18. The semiconductor device of claim 16, wherein the wire bonding region is a linearly-shaped region formed at a substantially central portion of the semiconductor chip.

19. The semiconductor device of claim 16, wherein the dummy bond pads have different colors from the bond pads.

20. The semiconductor device of claim 16, wherein the dummy bond pads have different shapes from the bond pads.
